(19) United States
(12) Patent Application Publication
(10) Pub. No.: US 2026/0231741 A1
(43) Pub. Date: Aug. 6, 2026

(54) METHOD FOR MANUFACTURING TWO SUBSTRATES CALLED DONOR PSEUDO-SUBSTRATES EACH COMPRISING AT LEAST TWO TILES ON A CARRIER SUBSTRATE

(71) Applicant: Soitec, BERNIN (FR)

(72) Inventors: Odile Mourey, BERNIN (FR); François Xavier Darras, BERNIN (FR); Didier Landru, BERNIN (FR); Catherine Maddalon, BERNIN (FR)

(21) Appl. No.: 19/135,176

(22) PCT Filed: Dec. 19, 2023
(86) PCT No.: PCT/FR2023/052043

§ 371 Date: Jun. 3, 2025

(30) Foreign Application Priority Data
Dec. 19, 2022 (FR) FR2213807

(51) Int. Cl. H10P 90/00; H10N 30/072; H10P 10/00; H10P 54/20; H10P 54/40

(52) U.S. Cl. CPC H10P 90/22; H10N 30/072; H10P 10/14; H10P 54/20; H10P 54/40

(57) ABSTRACT

A method of manufacturing two substrates called pseudo-donor substrates, each comprising at least two wafer tiles on a carrier substrate, includes placing at least two tiles, on a first carrier substrate each tile having an initial thickness greater than or equal to 300 μm, so as to form a first pseudo-donor substrate comprising the at least two tiles, bonding the first pseudo-donor substrate to a second carrier substrate via the tiles, separating the tiles into two portions of a first thickness and of a second thickness so as to keep a first portion of the tiles having the first thickness on the first pseudo-donor substrate and transfer the second portion of the tiles having the second thickness onto the second carrier substrate to form a second pseudo-donor substrate the second thickness being between 20% and 80% of the initial thickness of the tiles of the first pseudo-donor substrate.

### CROSS-REFERENCE TO RELATED APPLICATIONS

This application is a national phase entry under 35 U.S.C. § 371 of International Patent Application PCT/FR2023/052043, filed Dec. 19, 2023, designating the United States of America and published as International Patent Publication WO 2024/134078 A1 on Jun. 27, 2024, which claims the benefit under Article 8 of the Patent Cooperation Treaty of French Patent Application Serial No. FR2213807, filed Dec. 19, 2022.

### TECHNICAL FIELD

The present disclosure relates to a process for manufacturing two what are known as pseudo-donor substrates each comprising at least two wafer tiles on a carrier substrate.

### BACKGROUND

In the field of microelectronics, optics or optoelectronics, the design of multilayer structures sometimes requires a layer of a donor substrate to be transferred to a carrier substrate or receiver substrate.

One well-known layer transfer process is the Smart Cut™ process, in which, by implanting atomic species in the donor substrate, a weakened zone delimiting the layer to be transferred is formed, the donor substrate is bonded to the carrier substrate and the donor substrate is detached along the weakened zone in order to transfer the layer from the donor substrate to the carrier substrate. However, that process assumes that the donor substrate and the carrier substrate are the same size.

But, while silicon substrates with a relatively large size, typically a diameter of 300 mm, are available, other materials of interest currently only exist in the form of bulk substrates of smaller size, for example, with a diameter of 10 or 15 cm. Such is the case, in particular, for III-V semiconductor materials, comprising nitrides (for example, with regard to binary compounds, indium nitride (InN), gallium nitride (GaN) and aluminum nitride (AIN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AIP)).

Rather than transferring an entire layer of the donor substrate, a solution based on the Smart Cut™ process involves taking, from at least one donor substrate, one or more tiles and transferring the tiles to a first carrier substrate to form what is known as a pseudo-donor substrate, forming, by implanting atomic species, a weakened zone in each tile, bonding the pseudo-donor substrate to a second carrier substrate via the tiles, and detaching each tile along the weakened zone so as to transfer a portion of each tile to the second carrier substrate. The first and second substrates are the same size.

FIG. 1 shows a top view and a cross-sectional view of a carrier substrate S on which a plurality of tiles P1-P9 from at least one donor substrate have been disposed. In this example, there are nine tiles, which are distributed in three rows and three columns.

The structure can be manufactured using the “pick and place” technique, in which the donor substrate is cut into tiles and then each tile is placed on the surface of the carrier substrate with the aid of a robot.

However, since each tile is transferred individually to the first substrate, this technique can be very slow, especially since the precision required for aligning the tiles is demanding. Furthermore, the aforementioned materials of interest are sometimes particularly expensive, and, thus, it is desirable to minimize the potential waste formed during the transfer.

The thickness of the tiles placed on the carrier substrate is equal to the thickness of the donor substrate, namely on the order of a few hundred microns (for example, a thickness between 200 μm and 700 μm). During the course of the Smart Cut™ process, a portion of the tiles is transferred. The thickness of the transferred portion, which is on the order of a micron, is limited by the depth to which the atomic species are implanted. It is then possible to recycle the pseudo-donor substrate, using various surface treatment operations, so that it can be reused in a further process of the Smart Cut™ type. Such operations, aimed at making the surface finish of the tiles obtained by the Smart Cut™ process compatible with further bonding to a new carrier substrate, consume between 2 μm and 3 μm of the thickness of the tiles. Such a cycle comprising surface-treatment operations followed by the Smart Cut™ process may be repeated several times.

However, each cycle degrades the pseudo-donor substrate a little further: the defects associated with the successive implantations accumulate, and the uniformity of the thickness of the tiles of the pseudo-donor substrate decreases. In practice, the number of times that the pseudo-donor substrate can be used is lower than the theoretical number of tile portions that could be formed successively in the thickness of the tiles. As a result, across all of the cycles, only less than one hundred or so microns of tile thickness are used.

The solution of cutting the donor substrate in the thickness direction prior to cutting the tiles from the donor substrate is, for most materials, unsatisfactory. By way of example, indium phosphide (InP), which is available in the form of a substrate 100 mm in diameter and 625 μm thick, is a very brittle material. The cutting of such a material in such a way as to form two substrates of lesser thickness and the subsequent handling of the substrates are therefore difficult to achieve on an industrial scale.

### BRIEF SUMMARY

One objective of the present disclosure is to provide a process for the manufacture of pseudo-donor substrates comprising tiles placed on a carrier substrate, which is quicker than the “pick and place” process, the pseudo-donor substrates manufactured by the process making it possible, when they are used in a maximum number of successive Smart Cut™ processes, to generate less wastage of the materials from which the tiles are formed than the pseudo-donor substrates obtained directly from the “pick and place” method.

To this end, the present disclosure relates to a process for manufacturing two pseudo-donor substrates each comprising at least two wafer tiles on a carrier substrate, the process comprising the following successive steps:
placing at least two tiles on a first carrier substrate, each tile having an initial thickness greater than or equal to 100 μm, so as to form a first pseudo-donor substrate comprising the at least two tiles,
bonding the first pseudo-donor substrate to a second carrier substrate via the tiles,
separating the tiles into two portions of a first thickness and of a second thickness so as to keep a first portion of the tiles having the first thickness on the first pseudo-donor substrate and transfer a second portion of the tiles having the second thickness onto the second carrier substrate to form a second pseudo-donor substrate, the second thickness being between 20% and 80% of the initial thickness of the tiles of the first pseudo-donor substrate.

The process according to the present disclosure makes it possible to form at least two pseudo-donor substrates having tiles arranged on a carrier substrate and performing the tiling process of the “pick and place” type just the once.

By virtue of the present disclosure, following the use of the pseudo-donor substrates in a maximum number of successive Smart Cut™ processes, the substrates lead to a waste substrate comprising tiles of thickness smaller than the waste substrate that would be obtained from a pseudo-donor substrate manufactured in a simple “pick and place” process and used in the same number of successive Smart Cut™ processes.

In certain embodiments, the process further comprises cutting the at least two tiles from a donor substrate over the entire thickness of the donor substrate so that the at least two tiles have a thickness equal to the thickness of the donor substrate from which they have been cut.

In that case, the donor substrate advantageously has a diameter smaller than the diameters of the first carrier substrate and of the second carrier substrate.

In certain embodiments, the tiles are separated by mechanical cutting using a blade or by laser cutting.

In certain embodiments, the process comprises, prior to placing the at least two tiles on the first carrier substrate:
bonding a first donor substrate to a second donor substrate of the same diameter as the first donor substrate using a bonding layer, so as to form a thick donor substrate, and
cutting the at least two tiles from the thick donor substrate such that the initial thickness of each of the tiles is equal to the thickness of the thick substrate.

In that case, the first donor substrate and the second donor substrate advantageously have a diameter smaller than the diameters of the first carrier substrate and of the second carrier substrate.

The separating of the at least two tiles advantageously involves a selective attack on the bonding layer.

The separating of the tiles by selective attack on the bonding layer may be performed using a laser, using mechanical cutting with a blade, and/or chemical mechanical cutting.

In certain embodiments, the at least two tiles are placed successively on the first carrier substrate using a robot.

Particularly advantageously, the first carrier substrate has the same diameter as the second carrier substrate.

In certain embodiments, the first carrier substrate comprises the same material as the second carrier substrate.

Particularly advantageously, the first carrier substrate and/or the second carrier substrate may comprise silicon, glass, sapphire and/or polycrystalline silicon carbide.

In some embodiments, each tile comprises:
a semiconductor material, such as a III-V material, in particular, indium nitride (InN), gallium nitride (GaN), aluminum nitride (AlN), indium arsenide (InAs), gallium arsenide (GaAs), aluminum arsenide (AlAs), indium phosphide (InP), gallium phosphide (GaP) or aluminum phosphide (AIP), or a IV or IV-IV material, in particular, germanium or silicon carbide (SiC),
a piezoelectric material, such as lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AIN) or aluminum-scandium nitride (AlScN), and/or
an electrically insulating material, such as diamond, strontium titanate, yttria-stabilized zirconia or sapphire.

In some embodiments, the process further comprises:
bonding the first pseudo-donor substrate and, respectively, the second pseudo-donor substrate, onto a third carrier substrate, via the tiles of the first pseudo-donor substrate and, respectively, of the second pseudo-donor substrate,
separating the tiles into two portions of a third thickness and of a fourth thickness so as to keep a first portion of the tiles having the third thickness on the first pseudo-donor substrate and, respectively, on the second pseudo-donor substrate, and transfer a second portion of the tiles having the fourth thickness onto the third carrier substrate to form a third pseudo-donor substrate.

The fourth thickness of the second portion of tiles is advantageously between 20% and 80% of the first thickness and, respectively, of the second thickness.

The tiles are separated into the two portions of third thickness and fourth thickness by mechanical cutting using a blade or by laser cutting, or by any other method known to those skilled in the art.

Another aspect of the present disclosure is a method of transferring tiles from a substrate referred to as a pseudo-donor substrate to a receiver substrate, comprising:
forming a pseudo-donor substrate according to the process described hereinabove,
forming a weakened zone by implanting atomic species in each tile of the pseudo-donor substrate in order to define a portion to be transferred,
bonding the pseudo-donor substrate to a receiver substrate,
transferring a portion of the tiles from the pseudo-donor substrate onto the receiver substrate by detaching each tile along the weakened zone.

Particularly advantageously, the portion of each tile transferred from the pseudo-donor substrate has a thickness between 30 nm and 1.5 μm.

The receiver substrate advantageously comprises silicon, glass, sapphire, SiC and/or AlN.

### BRIEF DESCRIPTION OF THE DRAWINGS

Other features and advantages of the present disclosure will become apparent from the following detailed description, with reference to the appended drawings, in which:

FIG. 1 shows a top view and a cross-sectional view of a carrier substrate on which a plurality of tiles from a donor substrate have been placed;

FIGS. 2A to 2F depict one embodiment of the process for manufacturing pseudo-donor substrates according to the present disclosure, in which process, successively, tiles are cut from a donor substrate (FIG. 2A), the tiles are placed on a first carrier substrate so as to form a first pseudo-donor substrate (FIG. 2B), the first pseudo-donor substrate is bonded to a second carrier substrate via the tiles of the first pseudo-donor substrate (FIG. 2C), and the tiles are separated into two portions of a first thickness and of a second thickness so as to form a second pseudo-donor substrate (FIG. 2D), the first pseudo-donor substrate is bonded to a third carrier substrate via the tiles of the first pseudo-donor substrate (FIG. 2E) and the tiles are separated into two portions of a third thickness and of a fourth thickness so as to form a third pseudo-donor substrate (FIG. 2F);

FIGS. 3A to 3G depict another embodiment of the process according to the present disclosure, in which process, successively, a first donor substrate is bonded to a second donor substrate via a bonding layer so as to form a thick donor substrate (FIG. 3A), tiles are cut from the thick donor substrate (FIG. 3B), the tiles are bonded onto a first carrier substrate via the tiles of the first pseudo-donor substrate so as to form a first pseudo-donor substrate (FIG. 3C), the first pseudo-donor substrate is bonded to a second carrier substrate via the tiles of the first pseudo-donor substrate (FIG. 3D), and the tiles are separated into two portions of a first thickness and of a second thickness so as to form a second pseudo-donor substrate (FIG. 3E), the first pseudo-donor substrate is bonded to a third carrier substrate via the tiles of the first pseudo-donor substrate (FIG. 3F) and the tiles are separated into two portions of a third thickness and of a fourth thickness so as to form a third pseudo-donor substrate (FIG. 3G); and

FIGS. 4A to 4C depict a process of using the pseudo-donor substrates, this process comprising, successively, forming a weakened zone in the tiles of one of the pseudo-donor substrates by atomic implantation so as to delimit a portion of the tiles to be transferred (FIG. 4A), bonding the pseudo-donor substrate to a receiver substrate via the implanted tiles (FIG. 4B), and cutting the pseudo-donor substrate along the weakened zone so as to transfer the portion of the tiles that are delimited by the weakened zone (FIG. 4C).

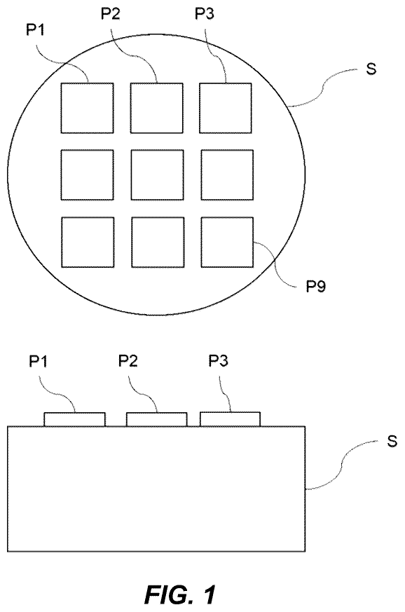

For the sake of legibility, the drawings have not necessarily been drawn to scale.

### DETAILED DESCRIPTION

The present disclosure relates to a process for manufacturing at least two substrates referred to as pseudo-donor substrates.

In the present description, what is meant by a pseudo-donor substrate is a substrate comprising tiles placed on a carrier substrate, the pseudo-donor substrate being able to be used for transferring thin layers of the active material of which the tiles are made onto a receiver substrate, for example, using a process of the Smart Cut™ type.

The use of such a pseudo-donor substrate is of particular benefit if the active material is not available in the form of large-sized substrates.

In the process according to the present disclosure, a first pseudo-donor substrate is manufactured by placing at least two tiles on a carrier substrate. The other pseudo-donor substrates are manufactured from this first pseudo-donor substrate by bonding the first pseudo-donor substrate onto other carrier substrates via the tiles and by separating the tiles from the first donor substrate in such a way as to transfer a portion of same onto each of the other carrier substrates. This advantageously makes it possible to dispense with the need for additional tile-placement steps.

Two embodiments of the process for manufacturing pseudo-donor substrates according to the present disclosure are described in greater detail hereinafter. Since the present disclosure extends to a process for transferring an active layer using one of these pseudo-donor substrates, one embodiment of such a transfer process is also described.

### First Embodiment of the Manufacture of Pseudo-Donor Substrates

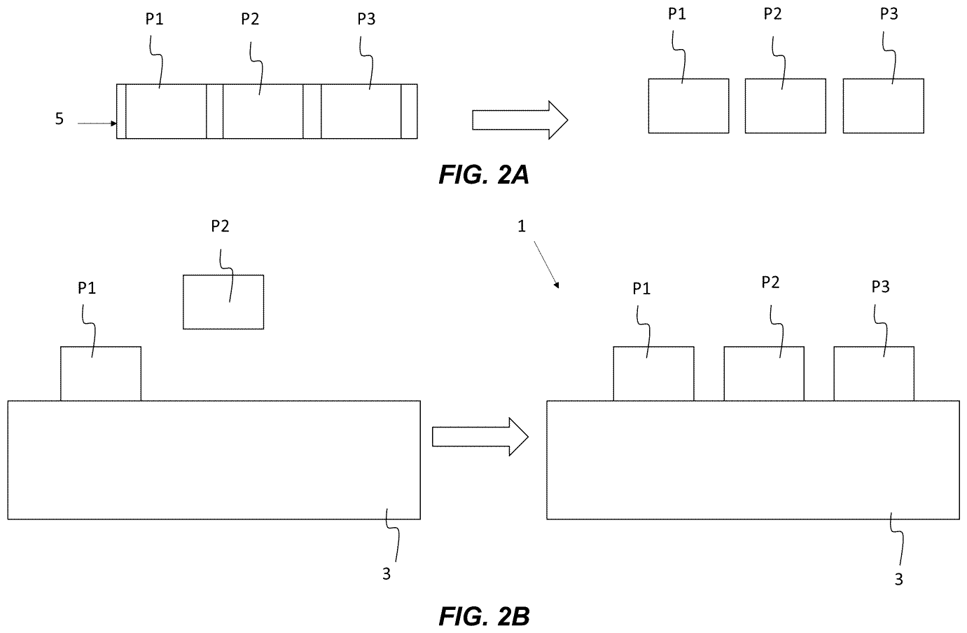

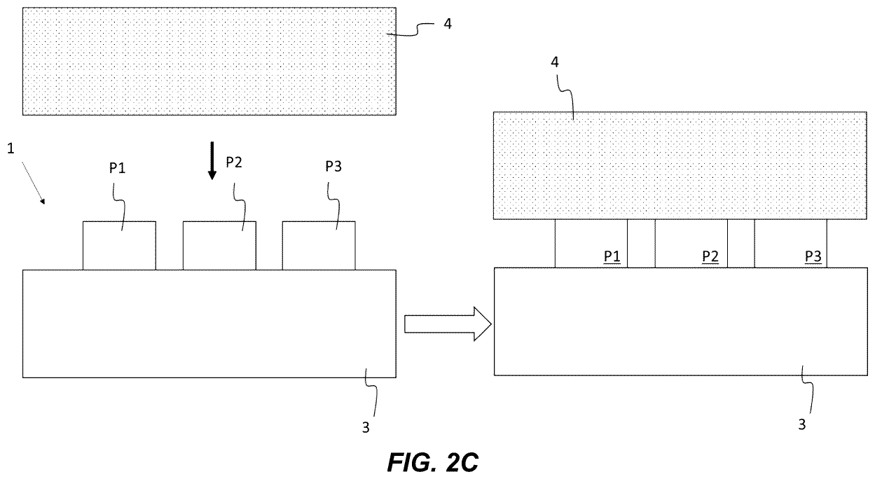

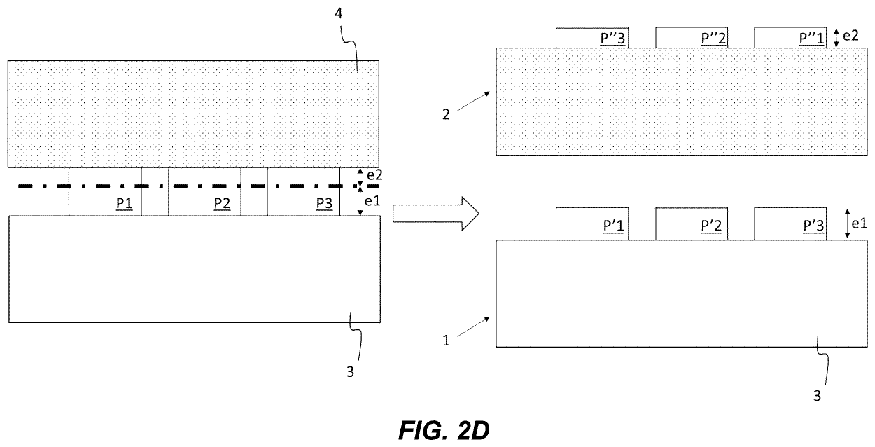

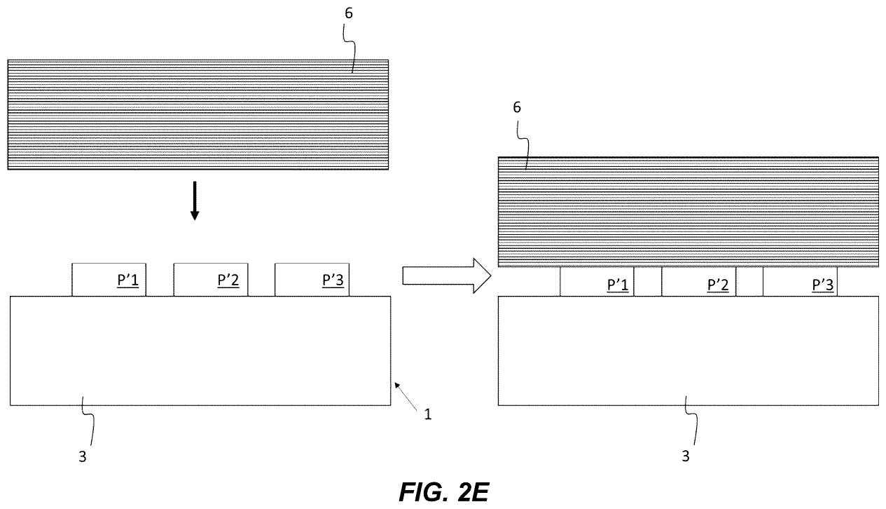

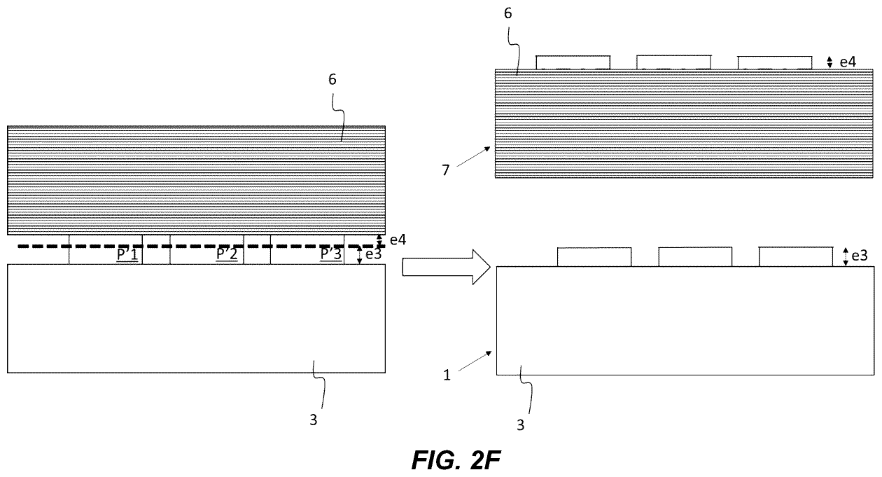

FIGS. 2A to 2F schematically illustrate a first particular embodiment of the process according to the present disclosure comprising placing the tiles P1, P2, P3 on a first carrier substrate 3 so as to form a first pseudo-donor substrate 1, transferring a first portion of the tiles P1, P2, P3 from the first pseudo-donor substrate 1 onto a second carrier substrate 4 so as to form a second pseudo-donor substrate 2, and finally, transferring a second portion of the tiles onto a third carrier substrate 6 so as to form a third pseudo-donor substrate 7.

According to this first embodiment, the tiles P1-P3 are cut from a donor substrate 5 as depicted in FIG. 2A. The tiles P1-P3 can be cut using any technique known to those skilled in the art. It may, in particular, be carried out by sawing and/or cleavage, or else by laser cutting. It may also, for example, be combined with a step of partial plasma etching of the cutting lines, a technique also known as “plasma dicing.”

The tiles P1-P3 are cut from the donor substrate 5 preferably over the entire thickness of the donor substrate 5, so that each tile P1-P3 has a thickness equal to the thickness of the donor substrate 5 from which the tiles have been cut.

Advantageously, the tiles P1-P3 are made of a material that is not commercially available in the form of a donor substrate with large dimensions. Thus, the donor substrate 5 may have a diameter smaller than 30 cm, for example, on the order of 10 or 15 cm. Such is the case, in particular, for III-V semiconductor materials, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AlP)). This is also the case for IV or IV-IV semiconductor compounds, for example, germanium and silicon carbide.

The tiles P1-P3 may also be made of a piezoelectric material, for example, lithium tantalate (LiTaO₃) or else lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN) or aluminum-scandium nitride (AlScN) (this being a non-limiting list).

The tiles P1-P3 may also be made of an electrically insulating material, for instance, diamond, strontium titanate (SrTiO₃), yttria-stabilized zirconia (YSZ) or else sapphire.

Each tile P1-P3 has a minimum initial thickness of 100 μm, preferably an initial thickness between 300 μm and 600 μm, more preferably still, an initial thickness between 400 μm and 600 μm, this initial thickness also advantageously being equal to the thickness of the donor substrate 5.

FIG. 2B illustrates the placing of the tiles P1-P3 on the first carrier substrate 3 to form a first pseudo-donor substrate 1 comprising the tiles P1-P3 and the first carrier substrate 3.

The first carrier substrate 3 advantageously has a larger diameter than the donor substrate 5. The first carrier substrate 3 comprises, for example, any material available in a larger substrate size than the donor material such as silicon, glass, polycrystalline SiC, sapphire (Al₂O₃), or any other semiconductor material available in a large diameter (which is to say a diameter greater than or equal to 200 or 300 mm). Given the difference in size between the donor substrate 5 and the first carrier substrate 3, several donor substrates 5 may be necessary to tile the entire surface of the first carrier substrate 3, depending on the desired tiling density.

The placing of each tile P1-P3 may be carried out using the “Pick and Place” technique, in which a robot takes hold of a tile previously cut from the donor substrate 5 and places it at a predetermined location on the first carrier substrate 3. The tiles P1-P3 are therefore placed successively on the first carrier substrate 3.

In certain embodiments, each tile P1-P3 adheres to the first carrier substrate 3 by molecular adhesion. To this end, surface treatments of the tiles P1-P3 and/or of the first carrier substrate 3 may be carried out beforehand in order to promote good molecular adhesion. These treatments may comprise, in particular, cleaning, the deposition of a bonding layer such as a silicon oxide (SiO₂), plasma activation before bonding, and annealing.

In other embodiments, the bonding of the tiles P1-P3 to the first carrier substrate 3 may involve an intermediate bonding layer, for example, a polymer bonding layer, a eutectic bonding layer or a ceramic bonding layer.

FIG. 2C illustrates the bonding of the first pseudo-donor substrate of FIG. 2B to a second carrier substrate 4 via the tiles P1-P3.

The same way as for the first carrier substrate 3, the second carrier substrate 4 advantageously has a diameter greater than the diameter of the donor substrate 5. The second carrier substrate 4 comprises, for example, any material available in a larger substrate size than the donor substrate material such as silicon, glass, polycrystalline SiC, Al₂O₃, or any other semiconductor material available in a large diameter and allowing implementation of a bonding step.

In one particular embodiment of the bonding of the first pseudo-donor substrate 1 of FIG. 2B to the second carrier substrate 4, the second carrier substrate 4 has the same diameter as the first carrier substrate 3, for example, on the order of 300 mm, and/or the second carrier substrate 4 comprises the same material as the first carrier substrate 3.

Particularly advantageously, each tile P1-P3 adheres to the second carrier substrate 4 by molecular adhesion. To this end, surface treatments of the tiles P1-P3 and/or of the second carrier substrate 4 may be carried out beforehand in order to promote good molecular adhesion. Depending on the materials being considered, these treatments may, in particular, comprise cleaning, the deposition of a bonding layer such as a silicon oxide (SiO₂), plasma activation before bonding, and/or Chemical Mechanical Polishing (CMP). Moreover, an annealing operation is generally implemented after bonding to strengthen the adhesion.

Next, with reference to FIG. 2D, the tiles are separated into two portions of a first thickness e1 and of a second thickness e2 so as to keep a first portion P′1-P′3 of the tiles having the first thickness e1 on the first pseudo-donor substrate 1 and transfer a second portion P″1-P″3 of the tiles having the second thickness e2 onto the second carrier substrate 4 to form a second pseudo-donor substrate 2.

The second thickness e2 is between 20% and 80% of the initial thickness of the tiles P1-P3 of the first pseudo-donor substrate 1, so that the second thickness e2 is preferably between 20 μm and 560 μm, more preferably still, between 200 μm and 400 μm.

The tiles P1-P3 may be separated by mechanical cutting using a blade, by laser cutting, or by any other cutting technique that is compatible with the material that is to be cut. In any event, the tiles cannot be separated using the Smart Cut™ process because the first and second thicknesses are far greater than the implantation depth accessible to the implantation devices that are industrially available (the depth being on the order of 1 μm).

Thus, the process according to the present disclosure advantageously enables the manufacture of two pseudo-donor substrates by implementing just the one “pick and place” step of placing the tiles on a donor substrate. As these “pick and place” steps are lengthy and awkward, the process according to the present disclosure is quicker than a process involving manufacturing each pseudo-donor substrate by placing tiles on a carrier substrate.

Optionally, the process according to this embodiment may further comprise bonding the first pseudo-donor substrate 1 (depicted in FIG. 2E) onto a third carrier substrate 6, via the tiles P′1-P′3 of the first pseudo-donor substrate 1.

In the same way as for the first carrier substrate 3 and the second carrier substrate 4, the third carrier substrate 6 advantageously has a diameter greater than the diameter of the donor substrate 5. The third carrier substrate 6 comprises, for example, any material available in a larger substrate size than the donor substrate material such as silicon, glass, polycrystalline SiC, sapphire, or any other semiconductor material available in a large diameter.

According to one particular embodiment of the bonding of the third carrier substrate 6 to the first pseudo-donor substrate 1, the third carrier substrate 6 has the same diameter as the first carrier substrate 3 and the second carrier substrate 4 and/or comprises the same material as the first carrier substrate 3 and the second carrier substrate 4.

Particularly advantageously, each portion P′1-P′3 adheres to the third carrier substrate 6 by molecular adhesion. Since the cutting leads to degradation of the crystalline quality of the tile and/or to surface roughness that cannot be used directly for molecular bonding, surface treatments may be performed on the tiles P′1-P′3 and/or on the third carrier substrate 6 beforehand in order to promote good molecular adhesion. These treatments may comprise, in particular, cleaning, the deposition of a bonding layer such as a silicon oxide (SiO₂), plasma activation before bonding, and/or polishing (CMP). The person skilled in the art may select the most suitable technique particularly according to the materials concerned and/or according to the cutting technique. However, if the bonding technique does not require a particularly low level of roughness, for example, when a polymer adhesive is employed, it is possible to dispense with any surface treatment. Moreover, an annealing operation is generally implemented after bonding to strengthen the adhesion.

With reference to FIG. 2F, the method then further comprises separating the tiles P′1-P′3 into two portions of a third thickness e3 and of a fourth thickness e4 so as to keep a first portion of the tiles having the third thickness e3 on the first pseudo-donor substrate 1 and transfer a second portion of the tiles having the fourth thickness e4 onto the third carrier substrate 6 to form a third pseudo-donor substrate 7.

The fourth thickness of the second portion of tiles is between 20% and 80% of the first thickness and, respectively, of the second thickness. The fourth thickness of the second portion of tiles is preferably between 40 μm and 300 μm, and more preferably still, between 100 μm and 250 μm.

In this case also, the tiles P′1-P3′ are separated into the two portions of third thickness e3 and fourth thickness e4 by mechanical cutting using a saw, by laser cutting, or by any other cutting technique that is compatible with the material that is to be cut.

As an alternative or in addition to the bonding of the first pseudo-donor substrate 1 to a third carrier substrate 6 so as to form a third pseudo-donor substrate 7, the second pseudo-donor substrate 2 may also be bonded to a new carrier substrate so as to form an additional pseudo-donor substrate (which has not been depicted).

Thus, at this stage in the process according to the present disclosure, it is possible to form up to four pseudo-donor substrates from a single donor substrate assembly and a single tile-placement step, for example, using “pick and place” that was used on the occasion of the formation of the first pseudo-donor substrate 1.

The number of pseudo-donor substrates that can be formed from the first pseudo-donor substrate is dependent on the initial thickness of the donor substrate and on the precision of the cutting method.

The pseudo-donor substrates thus formed can be used to transfer portions of tiles of fine thickness onto a carrier substrate using the Smart Cut™ process.

The process of forming the pseudo-donor substrates can be repeated until pseudo-donor substrates are obtained that have a tile thickness between 50 μm and 200 μm, depending on the thickness that can be picked up by the Smart Cut™ process and the number of times that it is possible to recycle the pseudo-donor substrate.

### Second Embodiment of the Manufacture of Pseudo-Donor Substrates

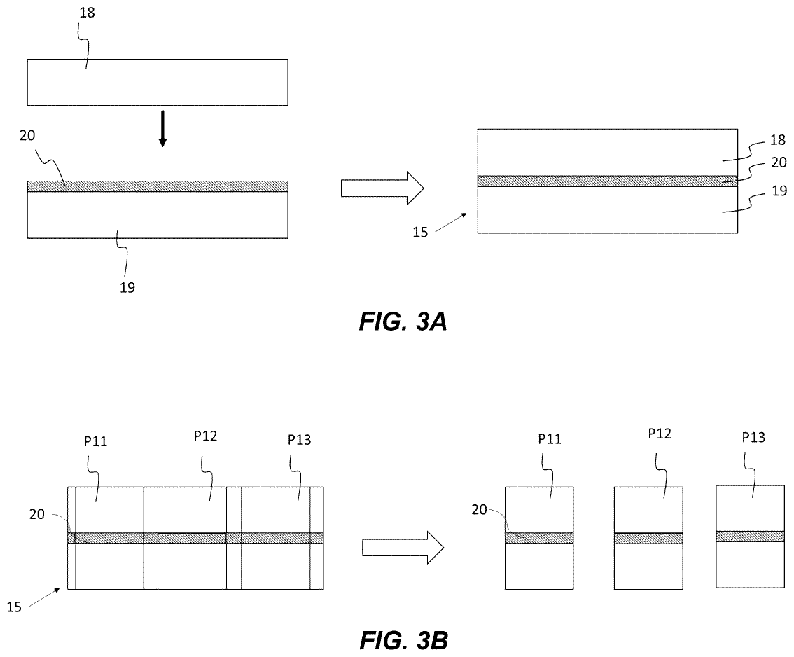

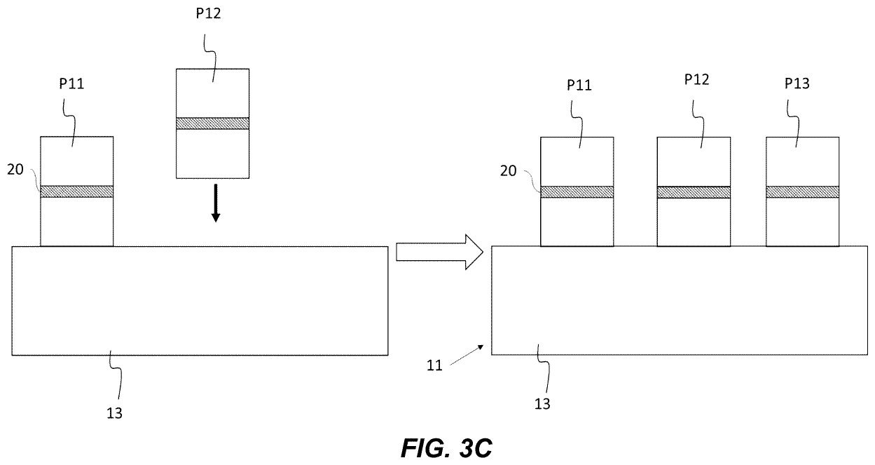

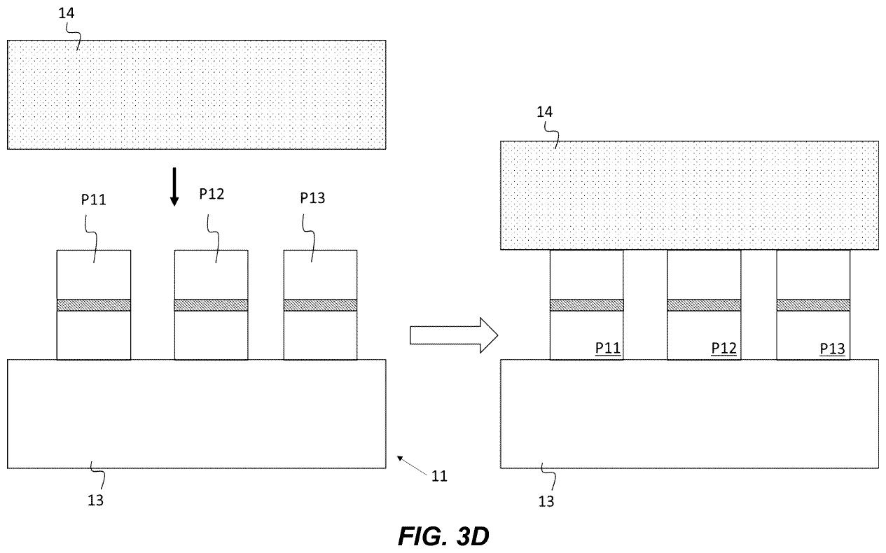

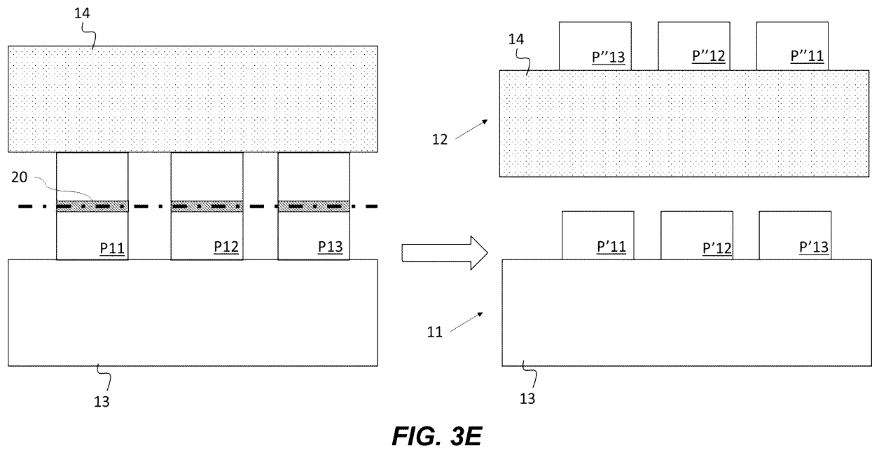

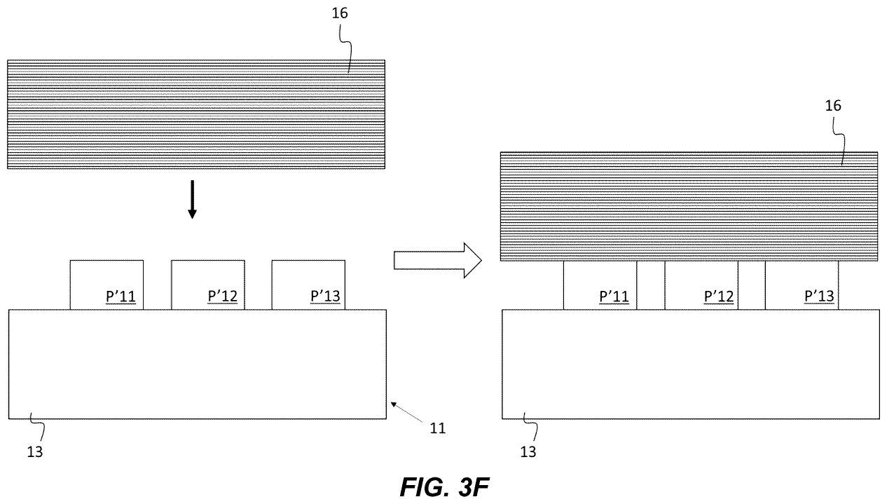

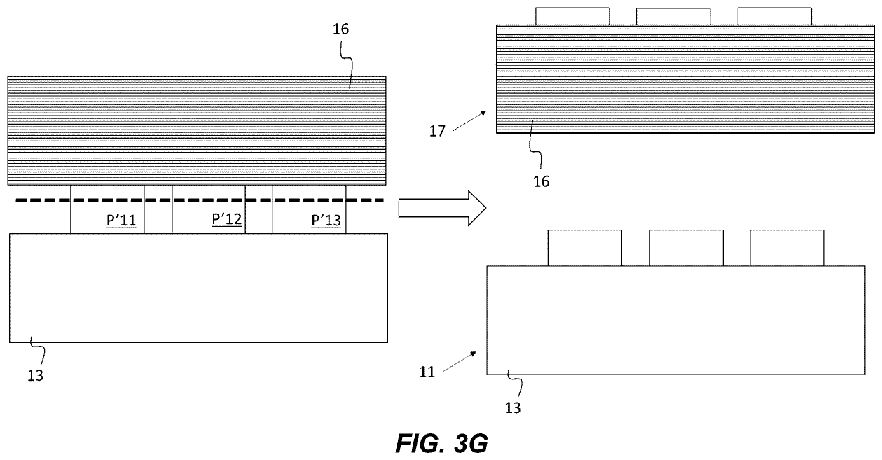

FIGS. 3A to 3G schematically illustrate a second embodiment of the process according to the present disclosure comprising placing the tiles P11, P12, P13 on a first carrier substrate 13 so as to form a first pseudo-donor substrate 11, then transferring a portion of the tiles P11, P12, P13 from the first pseudo-donor substrate 11 onto a second carrier substrate 14 so as to form a second pseudo-donor substrate 12.

According to this second embodiment of the present disclosure, a first donor substrate 18 is bonded to a second donor substrate 19 having the same diameter as the first donor substrate 18, via a bonding layer 20, so as to form a thick donor substrate 15 (depicted in FIG. 3A).

Advantageously, the first donor substrates 18 and the second donor substrate 19 are made of a material that is not commercially available in the form of a donor substrate with large dimensions. Thus, the first donor substrate 18 and the second donor substrate 19 may have a diameter smaller than 30 cm, for example, on the order of 10 or 15 cm. Such is the case, in particular, for III-V semiconductor materials, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AlP)). This is also the case for IV or IV-IV semiconductor compounds, for example, germanium and silicon carbide.

The first donor substrate 18 and the second donor substrate 19 may also be made of a piezoelectric material, for example, lithium tantalate (LiTaO₃) or else lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN) or aluminum-scandium nitride (AlScN) (non-limiting list).

The first donor substrate 18 and the second donor substrate 19 may also be made of an electrically insulating material, for instance, diamond, strontium titanate (SrTiO₃), yttria-stabilized zirconia (YSZ) or else sapphire.

The first donor substrate 18 and the second donor substrate 19 may be made of the same material or of different materials.

Depending on the material and diameter of the first and second donor substrates, the thickness of the substrates is generally between 120 μm and 700 μm.

The bonding layer 20 may be an oxide layer (oxide/oxide bonding being easy to implement on an industrial scale), a polymer bonding layer, a eutectic bonding layer or else a ceramic bonding layer, the material of the bonding layer being chosen for its ability to withstand the subsequent cutting step and for its ability to be selectively removed in relation to the material of the first and second donor substrate.

With reference to FIG. 3B, the tiles P11-P13 are cut from the thick donor substrate 15 such that the initial thickness of each of the tiles P11-P13 is equal to the thickness of the thick donor substrate 15.

Each tile P11-P13 has an initial thickness of between 400 μm and 1400 μm, preferably between 400 μm and 700 μm.

The tiles P11-P13 can be cut using any technique known to those skilled in the art. The cutting may, in particular, be carried out by sawing and/or cleavage, or else by laser cutting. It may also, for example, be combined with a step of partial plasma etching of the cutting lines, a technique also known as “plasma dicing.”

With reference to FIG. 3C, the tiles P11-P13 are then placed on the first carrier substrate 13 to form a first pseudo-donor substrate 11 comprising the first carrier substrate 13 and the tiles P11-P13.

In the same way as in the first embodiment, the placing of each tile P11-P13 may be performed by a robot, using the “pick and place” technique. The tiles P11-P13 are therefore placed successively on the first carrier substrate 13.

Each tile P11-P13 may adhere to the first carrier substrate 13 by molecular adhesion following potential surface treatments of the tiles P11-P13 and/or of the first carrier substrate 13 (cleaning, deposition of a bonding layer such as a silicon oxide (SiO₂), plasma activation prior to bonding and annealing), or by way of an intermediate bonding layer (polymer bonding layer, eutectic bonding layer, or ceramic bonding layer).

With reference to FIG. 3D, the first pseudo-donor substrate 11 is then bonded to a second carrier substrate 14 via the tiles P11-P13, for example, by molecular adhesion. In the same way as in the first embodiment, surface treatments of the tiles P11-P13 and/or the second carrier substrate 14 may be carried out beforehand in order to promote good molecular adhesion (cleaning, deposition of a bonding layer such as a silicon oxide (SiO₂), plasma activation, polishing, etc.).

In the same way as in the first embodiment also, the first carrier substrate 13 and the second carrier substrate 14 advantageously have a diameter greater than the diameter of the thick donor substrate 15. The first carrier substrate 13 and the second carrier substrate 14 comprise, for example, any material available in a substrate size larger than the donor substrate material such as silicon, glass, polycrystalline SiC, Al₂O₃, or any other semiconductor material available in a large diameter. The second carrier substrate 14 may possibly have the same diameter as the first carrier substrate 13, for example, on the order of 300 mm, and/or the second carrier substrate 14 comprises the same material as the first carrier substrate 3.

The tiles P11-P13 are then separated into two portions of a first thickness and of a second thickness so as to keep a first portion of the tiles P11-P13 having the first thickness on the first pseudo-donor substrate 11 and transfer a second portion of the tiles having the second thickness onto the second carrier substrate 14 to form a second pseudo-donor substrate 12.

Thus, in this embodiment also, the process advantageously enables two pseudo-donor substrates to be manufactured by having implemented just the once the lengthy and awkward step of placing the tiles on a carrier substrate, for example, using the “pick and place” method. The process according to the present disclosure is therefore quicker than the process involving systematically employing the “pick and place” method in order to form each pseudo-donor substrate.

With reference to FIG. 3E, according to this second embodiment, the separating of the tiles P11-P13 preferably comprises a selective attack on the bonding layer 20. The separating of the tiles by selective attack on the bonding layer 20 may be performed using a laser, using mechanical cutting with a blade, and/or chemical mechanical cutting. In any event, the tiles cannot be separated using the Smart Cut™ process because the first and second thicknesses are far greater than the implantation depth accessible to the implantation devices that are industrially available (the depth being on the order of 1 μm).

Once the tiles have been separated, any bonding-layer residue is removed in order to expose the free surface of the tiles. If necessary, a finishing treatment, such as a chemical mechanical polishing and/or a planarization, is performed in order to obtain a tile surface finish suited to the subsequent use of the tiles.

According to this embodiment also, the process according to the present disclosure may further comprise:
bonding the first pseudo-donor substrate 11 and, respectively, the second pseudo-donor substrate 12, onto a third carrier substrate 16, via the tiles P′11-P′13 of the first pseudo-donor substrate 11 and, respectively, of the second pseudo-donor substrate 12 (depicted in FIG. 3F in the case of the first pseudo-donor substrate 11, not depicted for the case of the second pseudo-donor substrate 12),
separating the tiles P′11-P′13 into two portions of a third thickness e13 and of a fourth thickness e14 so as to keep a first portion of the tiles having the third thickness on the first pseudo-donor substrate 11 and, respectively, on the second pseudo-donor substrate 12, and transfer a second portion of the tiles having the fourth thickness onto the third carrier substrate 16 to form a third pseudo-donor substrate 17 (depicted in FIG. 3G in the case of the second pseudo-donor substrate 12).

This variant of the process according to the present disclosure advantageously makes it possible to generate up to four pseudo-donor substrates by having implemented just the once the step of placing the tiles on a carrier substrate, so as to form a first pseudo-donor substrate.

According to other variants of the process, the first, second and third pseudo-donor substrates may even be bonded to other carrier substrates, so as to generate additional pseudo-donor substrates.

As a preference, all the pseudo-donor substrates obtained by the pseudo-donor substrate manufacturing process according to the present disclosure have a tile thickness between 50 and 300 μm.

Process for transferring tiles from a pseudo-donor substrate to a receiver substrate The present disclosure extends to a process for transferring tiles from a pseudo-donor substrate to a receiver substrate.

The process for transferring tiles comprises the formation of a pseudo-donor substrate according to any one of the embodiments of the pseudo-donor substrate manufacturing process described above. By way of example, the pseudo-donor substrate may be the first pseudo-donor substrate 1 taken up after the formation of the second pseudo-donor substrate 2 (as depicted in FIG. 2D) or after the formation of the third pseudo-donor substrate 7 (as depicted in FIG. 2F). By way of further example, the pseudo-donor substrate may be the second pseudo-donor substrate 2 (depicted in FIG. 2D) or the third pseudo-donor substrate 7 (depicted in FIG. 2F).

Alternatively, the pseudo-donor substrate may be the first pseudo-donor substrate 11 after the formation of the second pseudo-donor substrate 12 (as depicted in FIG. 3E) or after the formation of the third pseudo-donor substrate 17 (as depicted in FIG. 3G). The pseudo-donor substrate may also be the second pseudo-donor substrate 12 (depicted in FIG. 3E) or the third pseudo-donor substrate 17 (depicted in FIG. 3G).

As a further alternative, the pseudo-donor substrate may be the first, second or third pseudo-donor substrate 1, 2, 7 or the first, second or third pseudo-donor substrate 11, 12, 17 after they have been used to form additional pseudo-donor substrates (not depicted) or the additional pseudo-donor substrates (likewise not depicted).

As a preference, the tiles of the pseudo-donor substrate of the tile transfer process according to the present disclosure have a thickness between 50 μm and 300 μm.

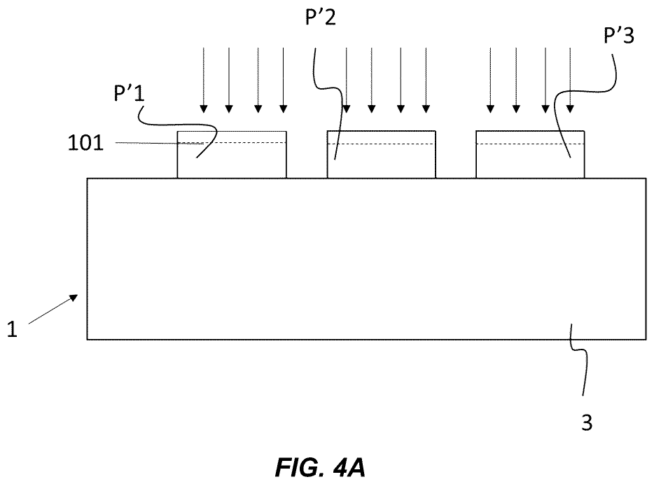

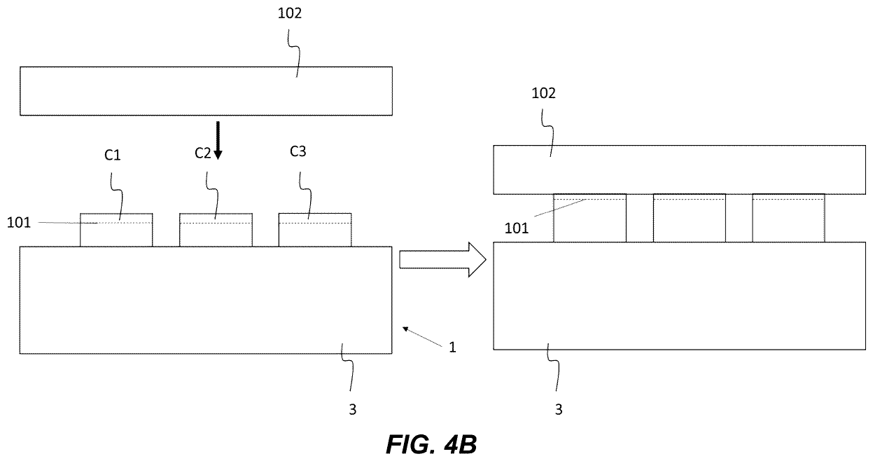

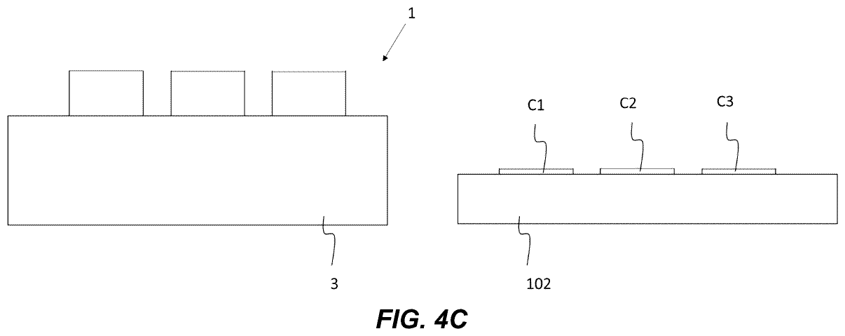

By way of example, the implementation of the series of operations in the tile transfer process is depicted in FIGS. 4A to 4C, starting from the first pseudo-donor substrate 1 after the formation of the second pseudo-donor substrate 2.

With reference to FIG. 4A, the tile transfer process according to the present disclosure comprises the formation of a weakened zone 101 in each tile (in the case of FIG. 4A, the tiles P′1-P′3) of the pseudo-donor substrate already manufactured (in the case of FIG. 4A, the pseudo-donor substrate 1) so as to delimit a surface layer of the tiles C1, C2, C3, which layer is intended to be transferred onto a receiver substrate 102.

As schematically indicated by the arrows, the weakened zone 101 is advantageously formed by the implantation of atomic species, such as hydrogen and/or helium, in the tiles, at a depth corresponding to the thickness of the layer C1, C2, C3 that is to be transferred.

The pseudo-donor substrate is then bonded to the receiver substrate 102, as illustrated in FIG. 4A, via the tiles.

The receiver substrate 102 has the same diameter as the pseudo-donor substrate, for example, on the order of 300 mm. The receiver substrate 102 comprises silicon, glass, sapphire, SiC, AlN and/or any other semiconductor material of interest that has a substrate size that is greater than that of the initial donor substrate.

In order to allow the tiles to be bonded collectively onto the receiver substrate, the tiles need to have the same thickness. To this end, it may be necessary, prior to bonding, to carry out an abrasion (grinding) operation in order to bring the tiles to uniform thickness and then perform a smoothing operation in order to render the surface of the tiles compatible with bonding.

Particularly advantageously, each tile adheres to the receiver substrate 102 by molecular adhesion. To this end, surface treatments of the tiles and/or of the second carrier substrate may be carried out beforehand in order to promote good molecular adhesion.

With reference to FIG. 4C, the tiles are then detached along the weakened zone 101 in order to transfer the layers C1, C2, C3 delimited by the weakened zone 101 onto the receiver substrate 102.

The transferred layers C1, C2, C3 generally have a thickness of between 30 nm and 1.5 μm.

Advantageously, the one same pseudo-donor substrate is reused several times in the steps of forming a weakened zone, bonding and cutting along the weakened zone, so that on each iteration of the steps a new portion of the tiles of the pseudo-donor substrate is transferred onto a new receiver substrate 102.

Between each transfer, the tile surface formed by the detachment along the weakened zone 101 is treated in order to achieve a roughness and a surface finish that enable good-quality bonding to the new receiver substrate 102. By way of example, such treatment may comprise, depending on the material of the tiles: chemical-mechanical polishing, fine-grit grinding, chemical etching, plasma treatment, the depositing of a smoothing layer and/or a heat treatment. Carrying out such a surface treatment may, depending on the treatment considered, consume a tile thickness on the order of 0.5 μm to 5 μm.

As a preference, several layer-transfer cycles are performed successively using the same pseudo-donor substrate, each cycle comprising the steps of forming a weakened zone, bonding, cutting along the weakened zone and surface treatment. Thus, the one same pseudo-donor substrate can be reused between once and thirty times so that the looping of the cycles consumes between 1 and 6 μm of tile thickness in total. Reusing the one same pseudo-donor substrate in a plurality of cycles therefore makes it possible to consume a greater thickness of the potentially rare and expensive material of which the tiles are made, thus limiting the wastage of the material. However, because each cycle degrades the pseudo-donor substrate a little further (defects in uniformity, unrepaired modification to the crystal structure, degradation to the edges of the tiles, breakage of the pseudo-donor substrate), the pseudo-donor substrate can be reused only a limited number of times. In practice, if less than 50% of the surface area of the tiles is unable to be bonded, the pseudo-donor substrate is considered to be no longer usable.

Thus, the pseudo-donor substrate manufacturing process according to the present disclosure advantageously enables the formation of pseudo-donor substrates having an initial tile thickness that is smaller than the donor substrate from which they are obtained made of the same material.

By way of example, the process for manufacturing pseudo-donor substrates from a substrate made of indium phosphide (InP) of a thickness of 625 μm and a diameter of 100 mm, allows the manufacture of pseudo-donor substrates exhibiting InP tiles of a minimum thickness of 100 μm, such that after 15 cycles, a thickness of 75 μm of the tiles has been consumed (at a rate of 5 μm per cycle), and such that the thickness scrapped is just 15 μm, rather than the 550 μm that would be the case if tiles of an initial thickness of 625 μm were used in the same number of cycles.

1. A method of manufacturing two pseudo-donor substrates each comprising at least two wafer tiles on a carrier substrate, the process comprising:
placing at least two tiles on a first carrier substrate, each tile having an initial thickness greater than or equal to 100 μm, so as to form a first pseudo-donor substrate comprising the at least two tiles;
bonding the first pseudo-donor substrate to a second carrier substrate via the tiles; and
separating the tiles into two portions of a first thickness and of a second thickness so as to keep a first portion of the tiles having the first thickness on the first pseudo-donor substrate and transfer a second portion of the tiles having the second thickness onto the second carrier substrate to form a second pseudo-donor substrate, the second thickness being between 20% and 80% of the initial thickness of the tiles of the first pseudo-donor substrate.

2. The method of claim 1, further comprising cutting the at least two tiles from a donor substrate over the entire thickness of the donor substrate so that the at least two tiles have a thickness equal to the thickness of the donor substrate from which they have been cut.

3. The method of claim 2, wherein the donor substrate has a diameter smaller than the diameters of the first carrier substrate and of the second carrier substrate.

4. The method of claim 1, wherein the tiles are separated by mechanical cutting using a blade or by laser cutting.

5. The method of claim 1, further comprising, prior to placing the at least two tiles on the first carrier substrate:
bonding a first donor substrate to a second donor substrate of the same diameter as the first donor substrate using a bonding layer, so as to form a thick donor substrate; and
cutting the at least two tiles from the thick donor substrate such that the initial thickness of each of the tiles is equal to the thickness of the thick donor substrate.

6. The method of claim 5, wherein the first donor substrate and the second donor substrate have a diameter smaller than the diameters of the first carrier substrate and of the second carrier substrate.

7. The method of claim 5, wherein the separating of the at least two tiles involves a selective attack on the bonding layer.

8. The method of claim 7, wherein the separating of the tiles by selective attack on the bonding layer is performed using a laser, using mechanical cutting aided by a blade, and/or by a chemical treatment.

9. The method of claim 1, further comprising placing the at least two tiles successively on the first carrier substrate using a robot.

10. The method of claim 1, wherein the first carrier substrate has the same diameter as the second carrier substrate.

11. The method of claim 1, wherein the first carrier substrate comprises the same material as the second carrier substrate.

12. The method of claim 1, wherein the first carrier substrate and/or the second carrier substrate comprises silicon, glass, sapphire and/or polycrystalline SiC.

13. The method of claim 1, wherein each tile comprises:
a semiconductor material;
a piezoelectric material; and/or
electrically insulating material.

14. The method of claim 1, further comprising:
bonding the first pseudo-donor substrate and, respectively, the second pseudo-donor substrate onto a third carrier substrate, via the tiles of the first pseudo-donor substrate and, respectively, of the second pseudo-donor substrate; and
separating the tiles into two portions of a third thickness and of a fourth thickness so as to keep a first portion of the tiles having the third thickness on the first pseudo-donor substrate and, respectively, on the second pseudo-donor substrate, and transfer a second portion of the tiles having the fourth thickness onto the third carrier substrate to form a third pseudo-donor substrate.

15. The method of claim 14, wherein the fourth thickness of the second portion of tiles is comprised between 20% and 80% of the first thickness and, respectively, of the second thickness.

16. The method of claim 14, wherein the tiles are separated into the two portions of third thickness and fourth thickness by mechanical cutting using a blade or by laser cutting.

17. A method of transferring tiles from a pseudo-donor substrate to a receiver substrate, comprising:
forming a pseudo-donor substrate using a method according to claim 1;
forming a weakened zone by implanting atomic species in each tile of the pseudo-donor substrate in order to define a portion to be transferred;
bonding the pseudo-donor substrate to a receiver substrate; and
transferring a portion of the tiles from the pseudo-donor substrate onto the receiver substrate by detaching each tile along the weakened zone.

18. The method of claim 17, wherein the portion of each tile transferred from the pseudo-donor substrate has a thickness between 30 nm and 1.5 μm.

19. The method of claim 17, wherein the receiver substrate comprises silicon, glass, sapphire, SiC or AlN.

20. The method of claim 13, wherein each tile comprises:
a semiconductor material selected from among the group consisting of indium nitride (InN), gallium nitride (GaN), aluminum nitride (AlN), indium arsenide (InAs), gallium arsenide (GaAs), aluminum arsenide (AlAs), indium phosphide (InP), gallium phosphide (GaP), aluminum phosphide (AlP), germanium, and silicon carbide (SiC);
a piezoelectric material selected from among the group consisting of lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN), and aluminum-scandium nitride (AlScN); and/or
an electrically insulating material selected from among the group consisting of diamond, strontium titanate, yttria-stabilized zirconia and sapphire.
